(19) United States
(12) Patent Application Publication
(10) Pub. No.: US 2026/0358402 A1
(43) Pub. Date: Nov. 12, 2026

(54) SYSTEMS AND METHODS FOR MONITORING INVERTERS FOR FAULTS

(71) Applicants: Arif I. Sarwat, Miami, FL (US); Shahid Tufail, Miami, FL (US)

(72) Inventors: Arif I. Sarwat, Miami, FL (US); Shahid Tufail, Miami, FL (US)

(73) Assignee: The Florida International University Board of Trustees, Miami, FL (US)

(21) Appl. No.: 19/205,191

(22) Filed: May 12, 2025

(51) Int. Cl. G01R 31/28

(52) U.S. Cl. CPC G01R 31/2832

(57) ABSTRACT

Systems and methods for monitoring inverters for fault detection are provided. The power of statistics can be integrated with machine learning (ML) to detect faults in solar inverters. The computation of the deviation from the expected value can be carried out and collected for multiple field-installed solar inverters. Based on the current output of an inverter and the history of the frequency of various alerts and log, the occurrence of faults can be predicted ahead of time.

### BACKGROUND

The global shift towards renewable energy sources, driven by the urgent need to mitigate environmental impacts and ensure sustainable energy generation, has significantly increased the deployment of solar photovoltaic (PV) systems. At the heart of these PV systems are solar inverters, critical devices responsible for converting direct current (DC) produced by solar panels into alternating current (AC) compatible with the electric grid. Due to their crucial role, the operational reliability and performance efficiency of solar inverters directly influence the overall system effectiveness, financial return, and grid stability. However, these inverters are susceptible to various faults, including open-circuit, short-circuit, insulation degradation, overheating, and grid synchronization issues, potentially reducing system efficiency, compromising safety, and resulting in substantial financial losses.

Solar inverters must be maintained in good condition to ensure that they continue to function well and generate expected output. The primary maintenance of a solar inverter includes cleaning of the vents to maintain the inverter temperature under operating range, and inspection of electrical connections and wiring. In addition, monitoring the functioning of the inverter can assist in locating potential faults and addressing them before they develop into more serious ones.

### BRIEF SUMMARY

Embodiments of the subject invention provide novel and advantageous systems and methods for monitoring inverters for fault detection. The power of statistics can be integrated with machine learning (ML) to detect faults in solar inverters. The computation of the deviation from the expected value can be carried out and collected for multiple field-installed solar inverters. Based on the current output of an inverter and the history of the frequency of various alerts and log, the occurrence of faults can be predicted ahead of time.

In an embodiment, a system for monitoring inverters for faults can comprise: a plurality of inverters; a processor in operable communication with the plurality of inverters (e.g., direct current (DC)-alternating current (AC) inverters); and a machine-readable medium in operable communication with the processor and having instructions stored thereon that, when executed by the processor, perform the following steps: i) receiving data from the plurality of inverters; ii) performing preprocessing on the data received from the plurality of inverters to give preprocessed data; iii) calculating a Z-score for each inverter of the plurality of inverters using the preprocessed data, the Z-score being a measure of how far away a value for the respective inverter of an inverter property is from an expected mean value for the inverter property; iv) upon the Z-score for a respective inverter being at or below a predetermined threshold, determining that the respective inverter is operating normally; v) upon the Z-score for a respective inverter exceeding the predetermined threshold, determining that a fault exists with the respective inverter; vi) utilizing an ML model on the preprocessed data and the Z-scores for the plurality of inverters to determine if a fault exists in any inverter of the plurality of inverters; and vii) generating an alert for any inverter of the plurality of inverters determined to have a fault. The ML model can be a trained ML model. The ML model can be, for example, random forest, decision tree, K-Nearest Neighbor (KNN), or logistic regression. Step vi) can comprise using principal component analysis (PCA) and/or an autoencoder (AE) on the preprocessed data before utilizing the ML model. The performing of the preprocessing can comprise, for example, removing outliers in the data, removing duplicates in the data, and/or interpolating missing datapoints in the data. The instructions when executed can further comprise: viii) shutting down (and/or sending a shutdown signal for a maintenance worker to act on with respect to) any inverter of the plurality of inverters determined to have a fault to allow for maintenance on said inverter. The instructions when executed can further comprise: ix) repeating steps i)-viii) (or steps i)-vii)) at regular time intervals (e.g., every 5 minutes, every 10 minutes, every 15 minutes, or other interval), and this can be done for a (predetermined) set period of time (e.g., 1 day, 1 week, 1 month, 3 months, etc.). The system can further comprise a plurality of photovoltaic (PV) cells connected to the plurality of inverters, respectively. Each inverter of the plurality of inverters can be a solar inverter. The system can further comprise a grid and/or a load connected to the plurality of inverters. The system can further comprise a point of common coupling (PCC) between the load and the plurality of inverters.

In another embodiment, a method for monitoring inverters for faults can comprise: i) receiving (e.g., by a processor) data from a plurality of inverters (e.g., DC-AC inverters); ii) performing (e.g., by the processor) preprocessing on the data received from the plurality of inverters to give preprocessed data; iii) calculating (e.g., by the processor) a Z-score for each inverter of the plurality of inverters using the preprocessed data, the Z-score being a measure of how far away a value for the respective inverter of an inverter property is from an expected mean value for the inverter property; iv) upon the Z-score for a respective inverter being at or below a predetermined threshold, determining (e.g., by the processor) that the respective inverter is operating normally; v) upon the Z-score for a respective inverter exceeding the predetermined threshold, determining (e.g., by the processor) that a fault exists with the respective inverter; vi) utilizing (e.g., by the processor) an ML model on the preprocessed data and the Z-scores for the plurality of inverters to determine if a fault exists in any inverter of the plurality of inverters; and vii) generating (e.g., by the processor) an alert for any inverter of the plurality of inverters determined to have a fault. The ML model can be a trained ML model. The ML model can be, for example, random forest, decision tree, KNN, or logistic regression. Step vi) can comprise using PCA and/or an AE on the preprocessed data before utilizing the ML model. The performing of the preprocessing can comprise, for example, removing outliers in the data, removing duplicates in the data, and/or interpolating missing datapoints in the data. The method can further comprise: viii) shutting down (e.g., by the processor or manually by a person, after receiving the alert) any inverter of the plurality of inverters determined to have a fault to allow for maintenance on said inverter. The method can further comprise: ix) repeating (e.g., by the processor) steps i)-viii) (or steps i)-vii)) at regular time intervals (e.g., every 5 minutes, every 10 minutes, every 15 minutes, or other interval), and this can be done for a (predetermined) set period of time (e.g., 1 day, 1 week, 1 month, 3 months, etc.). The plurality of inverters can be connected to plurality of PV cells, respectively. Each inverter of the plurality of inverters can be a solar inverter. The plurality of inverters can be connected to a grid and/or a load. A PCC can be present between the load and the plurality of inverters.

### BRIEF DESCRIPTION OF DRAWINGS

FIG. 1 shows a framework for machine learning (ML)-based inverter fault detection, according to an embodiment of the subject invention.

FIG. 2 shows plots of true positive rate versus false positive rate for logistic regression with no principal component analysis (PCA) (top left), random forest with no PCA (top right), K-Nearest Neighbors (KNN) with no PCA (bottom left), and decision tree with no PCA (bottom right).

FIG. 3 shows plots of true positive rate versus false positive rate for logistic regression with PCA (top left), random forest with PCA (top right), decision tree with PCA (bottom left), and KNN with PCA (bottom right).

FIG. 4 shows types of faults and detection methods adopted.

FIG. 5 shows a scatter plot of three features (V_{dc}, Vₚᵥ, and I_{abc}). The circular data points are for healthy, and the triangular data points are for fault.

FIG. 6 shows a correlation analysis.

FIG. 7 shows a plot of explained variance ratio versus principal component number (left) and a plot of cumulative explained variance versus number of principal components (right), showing a Scree plot of principal components and a cumulative Scree plot, respectively. These plots together show a PCA analysis.

FIG. 8 shows a flow diagram of a method, according to an embodiment of the subject invention.

FIG. 9 shows a class distribution pie chart.

FIG. 10 shows a plot of loss versus epoch, showing a loss plot of autoencoders.

FIG. 11 shows a bar chart of feature importance for different features.

FIG. 12 shows a confusion matrix for all models.

FIG. 13 shows a plot of true positive rate versus false positive rate, showing the receiver operating characteristic (ROC) curve for different models.

FIG. 14 shows a bar chart of monthly alerts.

FIG. 15 shows a bar chart of warnings and faults.

FIG. 16 shows a bar chart of monthly alerts.

FIG. 17 shows a bar chart of inverter monthly alerts distribution.

FIG. 18 shows a bar chart of inverter alert distribution.

FIG. 19 shows a bar chart of inverter monthly alerts.

FIG. 20 shows a confusion matrix.

FIG. 21 shows a plot of intermittency in performance.

FIG. 22 shows a decision tree confusion matrix (left) and a random forest confusion matrix (right).

FIG. 23 shows a logistic regression confusion matrix (left) and a KNN confusion matrix (right).

FIG. 24 shows a table of an accuracy comparison with PCA.

FIG. 25 shows a table of an accuracy comparison with no PCA.

FIG. 26 shows a table of features in a grid-connected photovoltaic (PV) systems faults (GPVS-faults) dataset.

FIG. 27 shows a table of a summary of model performance.

FIG. 28 shows a table of a summary of results.

FIG. 29 shows a table of numerical coding for alerts.

FIG. 30 shows a decision tree algorithm that can be used with embodiments of the subject invention.

FIG. 31 shows a random forest algorithm that can be used with embodiments of the subject invention.

FIG. 32 shows a PCA algorithm that can be used with embodiments of the subject invention.

FIG. 33 shows an algorithm for inverter fault diagnosis that can be used with embodiments of the subject invention.

### DETAILED DESCRIPTION

Embodiments of the subject invention provide novel and advantageous systems and methods for monitoring inverters for fault detection. The power of statistics can be integrated with machine learning (ML) to detect faults in solar inverters. The computation of the deviation from the expected value can be carried out and collected for multiple field-installed solar inverters. Based on the current output of an inverter and the history of the frequency of various alerts and log, the occurrence of faults can be predicted ahead of time.

Detecting inverter faults rapidly and accurately is a vital task that ensures seamless operation, system reliability, and long-term profitability. Multiple factors, including weather, operating conditions, manufacturing defects, can significantly impact the reliability of the inverters. Ensuring the safe and reliable operation of solar inverters is of the utmost importance, which is why fault detection and diagnosis are critical. With the widespread adoption of solar energy systems, there is a need for a reliable way of predicting potential failures. While related art methods like model-based, rule-based, and signal-processing-based techniques have limitations, ML-based data-driven methods offer several advantages. A challenge with ML-based data-driven methods is data dependency and lack of critical data. Embodiments of the subject invention address this challenge by using statistics and integrating with ML.

Potential faults of solar inverters can be predicted based on the state of their internal components. By analyzing data collected from sensors and other monitoring devices, algorithms can be developed to detect anomalies or patterns that indicate a fault may occur. Another challenge is that it can be difficult to collect insight of a wide variety of components of inverters that may include insulated-gate bipolar transistors (IGBTs), capacitors, cooling fans, and other components. Other important factors that play a vital role in the functioning of the inverter are junction temperature, ambient temperature, the temperature inside the inverter, and internal and external humidity. Embodiments of the subject invention can determine potential failure/faults using combined statistical and ML algorithms that do not require large data logs.

Embodiments of the subject invention can provide assistance to maintenance crews for inverters by determining the inverters that are prone to failure, thereby allowing predictive maintenance to be performed and reducing the chances of reactive maintenance. Solar photovoltaic (PV) inverters play a critical role in the solar PV ecosystem but they also contribute to most of the faults in the solar PV ecosystem. The cost of reactive maintenance is very high, so embodiments of the subject invention can bring down overall maintenance cost by predicting failure/faults in advance. In addition, the ability to predict faults can enhance the lifespan of inverters. This is because cascading failures are one of the most common phenomena that reduces the lifespan, and embodiments of the subject invention can minimize the occurrence of cascading failures.

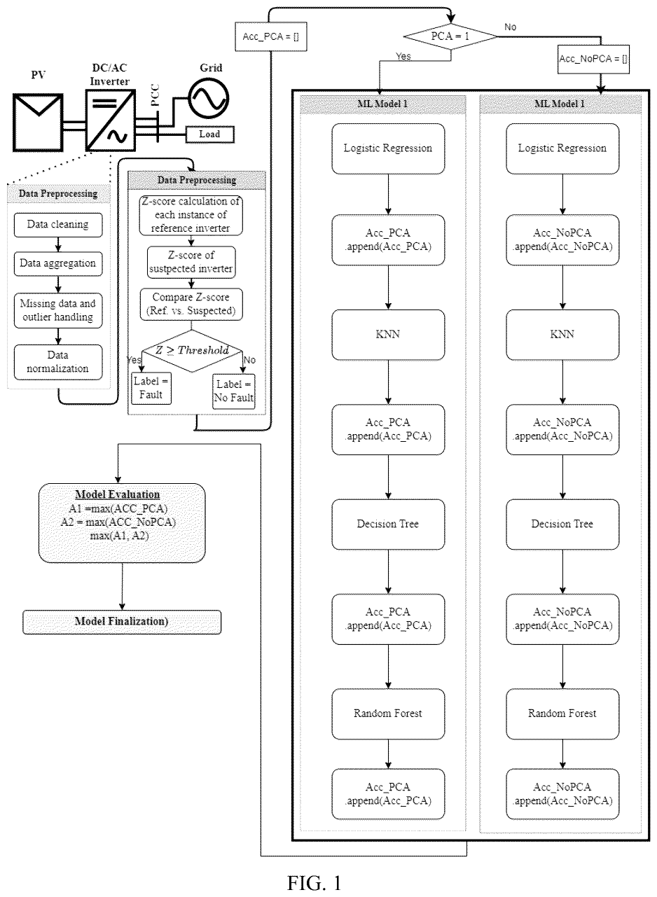

FIG. 1 shows a framework for fault detection, according to an embodiment of the subject invention. At first, data can be gathered/received from real solar PV sites for each of the various inverters. The data aggregators can collect all of the data that is provided to them from the inverters and can send it to at least one data preprocessor. Data analysis can be performed in the data preprocessor(s) to determine whether or not there is any kind of missing data, the seasonality of the missing data if it exists, and outliers in the data. Missing data removal/interpolation, outlier removal, and/or duplicate data removal are some tasks that may be performed during preprocessing. The preprocessed data can then be used to calculate the Z-score of the (or each) inverter at each time stamp with regard to the expected mean and standard deviation of the inverter output under ideal conditions. The following stage entails computing the ratio of the actual Z-score to the expected Z-score; if this ratio is higher than the threshold, the instance is considered to be malfunctioning; otherwise, it is considered to be operational. Following the completion of the data preparation assignment, an ML algorithm (e.g., logistic regression, decision tree classifier, K-Nearest Neighbor (KNN) classifier, or random forest classifier) can be implemented. Once the model has been completed, the trained model can be deployed, at which point it can categorize fresh data instances as having faults or no faults. In the event that a failure/fault occurs (e.g., a fault is predicted), it can send an alert to the maintenance staff so that they can take the appropriate corrective measures. In addition, the newly acquired data can be integrated to the previously learned data in order to include it in further training.

Logistic regression is a commonly used statistical model for predicting binary outcomes. The logistic regression can yield very high accuracy in a very short training time when the data is linearly separable. In the case of detecting faulty inverters, logistic regression can be used to predict whether an inverter is faulty or not based on a set of input features. These features can include data related to the inverter's temperature, voltage, and current. Logistic regression is a straightforward and easy-to-implement algorithm that explains the relationship between the input features and the binary output. Though, logistic regression does have certain limitations. It assumes a linear relationship between the input features and the output, which may not always be the case. Also, logistic regression is sensitive to outliers and may not work well for complex datasets with nonlinear relationships. More advanced algorithms like decision tree and random forest are typically better when the input data is complicated.

Decision trees are a ML method that is often used for classification problems. They divide the input space into partitions based on the attributes of the inputs. Decision trees are made by splitting the input data repeatedly based on what portion of information gives the most information gain. The end result of the decision tree is a set of conditions that can be used to put new data points.

KNN is another classifier that is used in a wide variety of classification problems, including load forecasting, dynamic pricing, grid stability and fault detection. It is a non-parametric and instance-based algorithm, which means it doesn't make any assumptions about how the data is actually distributed. Instead, it uses the whole set of data to make forecasts. One of the advantages of the KNN classifier is that it is simple and easy to implement. It also does not require any training process, making it a good choice for small datasets. Additionally, it can handle non-linear decision boundaries and work well with numerical and categorical data. However, the KNN classifier has some limitations as well. It can be sensitive to the choice of distance metric and can perform poorly in high-dimensional feature spaces. Also, it can be hard to find the closest neighbors for big datasets because it takes a lot of processing power.

One example of supervised ML is random forest. Random forests are built on a foundation that combines the output of many decision trees and then averages the results of the predictions of these combined trees. Because it combines the results of different decision trees, it can also be considered an example of ensemble learning. Random forest has been found to perform exceptionally well in situations in which the number of variables is significantly higher than the number of observations. Random Forest has a lot of advantages when it comes to classification problems. One of its best features is that it can deal with both number and categorical data. This makes it a flexible algorithm. It can also handle missing data and noisy or unimportant features. Additionally, the algorithm is able to detect complex relationships between features and can handle non-linear decision boundaries.

Principal component analysis (PCA) is a statistical technique used to reduce the dimensionality of a dataset while retaining as much of the original variation as possible. The basic idea of PCA is to identify the directions of maximum variance in the data and project the data onto a lower-dimensional subspace defined by these directions. PCA works by finding a set of orthogonal vectors, called principal components, that represent the directions of maximum variance in the data. The first principal component explains the most variation in the data, and each subsequent component explains as many variations as feasible. A common rule of thumb is to select the number of components that explain 80%-90% of the total variation in the data when determining the number of principal components. After identifying the principal components, the initial data can be projected onto the lower-dimensional subspace defined by these components. This generates a new set of variables, known as the principal component scores, that represent the data variation in a more compact manner. PCA is beneficial for a variety of applications, such as data visualization, feature extraction, and data compression. By reducing the dimensionality of the data, complex datasets can be simpler to analyze and interpret, and the risk of overfitting in machine learning models can be reduced.

In order to evaluate the performance of a given inverter, a Z-score comparison can be implemented between a reference inverter and the given inverter. The Z-score, also known as the standard score, is a widely used statistical measurement that describes the deviation of a data point from the mean of a dataset. It is used to standardize the data and make comparisons between data points in different datasets with different scales and distributions. One of the important properties of the Z-score is that it enables comparison of data points from different datasets with different units of measurement. By standardizing the data, Z-scores can be used to compare data points from datasets with different scales and distributions. This is because the Z-score provides a standardized way of measuring deviation from the mean. The Z-score is also useful in identifying outliers in a dataset. Outliers are data points significantly different from the other data points in the dataset. Z-scores can be used to detect outliers by comparing the Z-score of each data point with a predetermined threshold.

Embodiments of the subject invention increase the safety and stability of the grid while encouraging the broad use of PV systems as a viable source of clean energy. This is because faults can be detected and isolated more quickly compared to related art systems/methods. Embodiments provide an efficient instrument for improving the safety, stability, and dependability of green energy systems. This is a significant advantage as the movement toward renewable energy sources continues.

Embodiments of the subject invention provide a focused technical solution to the focused technical problem of how to efficiently predict faults in inverters (e.g., solar inverters connected to PV cells). The solution is provided by using a Z-score in combination with an ML model to efficiently and accurately predict faults in inverters before they occur. This technical solution is specific to inverter technology, addresses a technical problem within the field of inverter technology, and improves the inverter itself (by minimizing failure). Embodiments of the subject invention have the focused, technologically-specific practical application of generating alerts before an expected fault actually occurs in an inverter. The alert can be used to shut down such an inverter for maintenance, correction, and/or replacement, thereby improving the electrical grid having the inverter.

The methods and processes described herein can be embodied as code and/or data. The software code and data described herein can be stored on one or more machine-readable media (e.g., computer-readable media), which may include any device or medium that can store code and/or data for use by a computer system. When a computer system and/or processor reads and executes the code and/or data stored on a computer-readable medium, the computer system and/or processor performs the methods and processes embodied as data structures and code stored within the computer-readable storage medium.

It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), and magnetic and optical storage devices (hard drives, magnetic tape, CDs, DVDs); network devices; or other media now known or later developed that are capable of storing computer-readable information/data. Computer-readable media should not be construed or interpreted to include any propagating signals. A computer-readable medium of embodiments of the subject invention can be, for example, a compact disc (CD), digital video disc (DVD), flash memory device, volatile memory, or a hard disk drive (HDD), such as an external HDD or the HDD of a computing device, though embodiments are not limited thereto. A computing device can be, for example, a laptop computer, desktop computer, server, cell phone, or tablet, though embodiments are not limited thereto.

When ranges are used herein, combinations and subcombinations of ranges (e.g., any subrange within the disclosed range) and specific embodiments therein are intended to be explicitly included. When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

A greater understanding of the embodiments of the subject invention and of their many advantages may be had from the following examples, given by way of illustration. The following examples are illustrative of some of the methods, applications, embodiments, and variants of the present invention. They are, of course, not to be considered as limiting the invention. Numerous changes and modifications can be made with respect to embodiments of the invention.

### Example 1

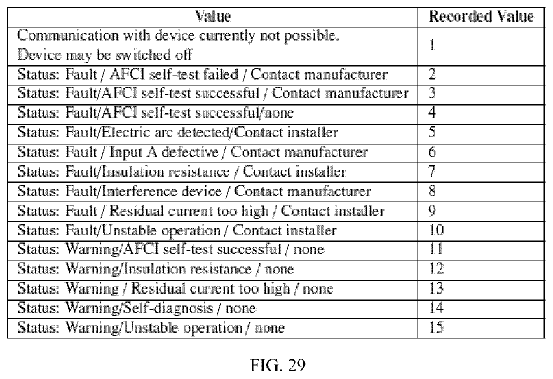

The framework shown in FIG. 1 was used to evaluate the performance of inverters. The analysis began with 46 solar inverters, and the performance of the inverters over the past three months was analyzed. Although inverters were installed in the same location, their performance was not identical under the same irradiance and ambient temperature. Out of 46, six inverters had high efficiency, but later, they failed during this analysis. There are 15 different warnings/faults that the inverter sends, as shown in the table in FIG. 29. In this analysis, two major notifications were found, one related to communication and the other an interference device directly related to the PV production output of the inverter.

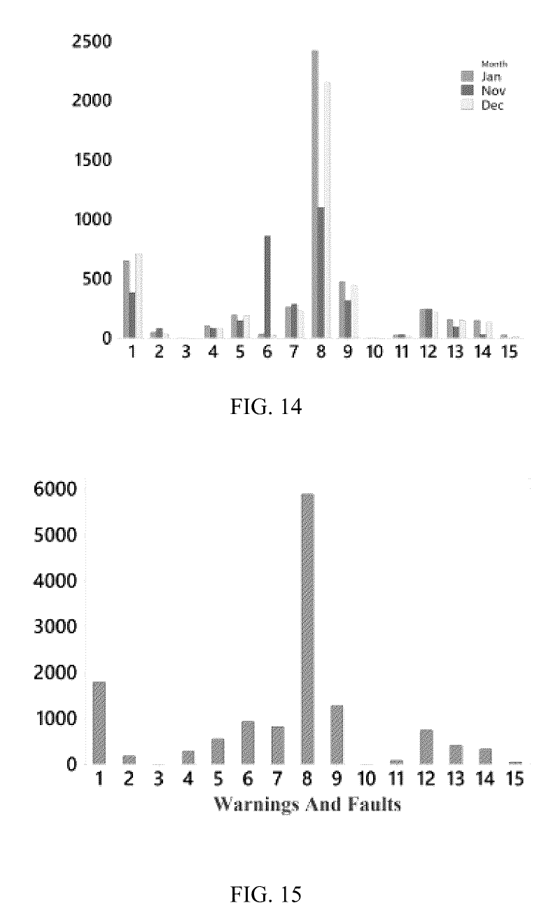

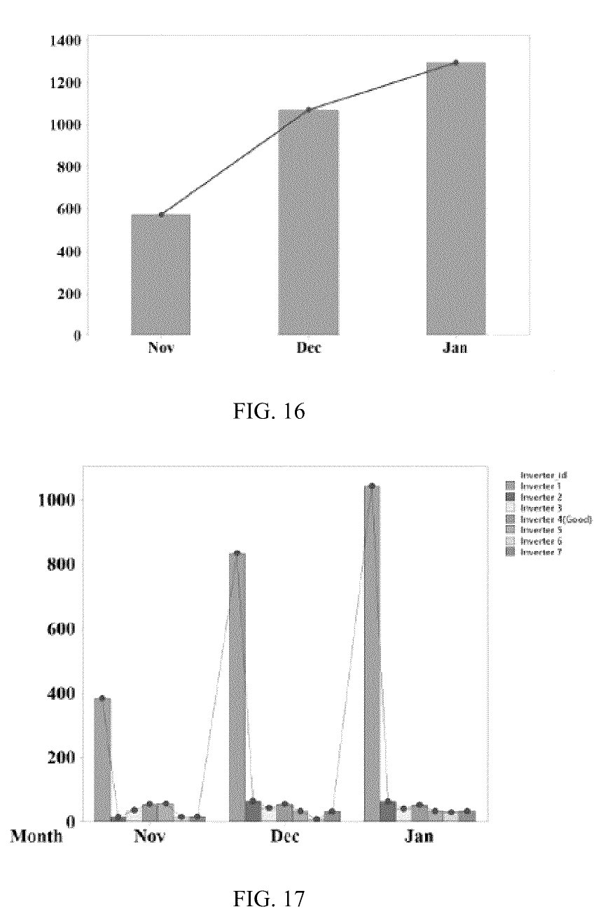

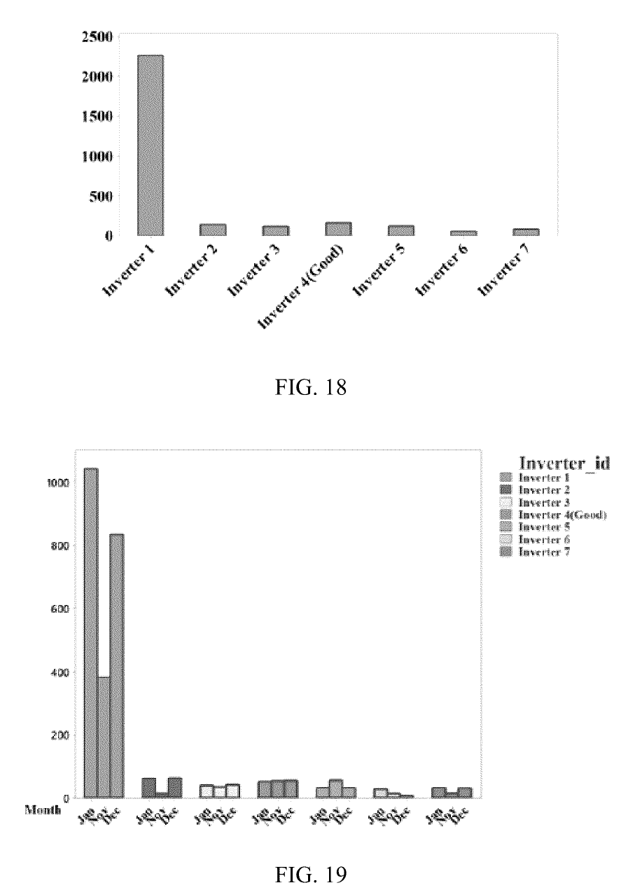

FIGS. 14 and 15 show monthly alerts and the frequency of all alerts, respectively. It was observed that before an inverter fails, there was an increase in the frequency of the alerts, with just over 1000 in November, followed by December with slightly over 2000, and finally, in January, it was a little lower than 2500 alerts as shown in FIG. 1. FIGS. 16 and 17 show monthly alerts frequency and inverter monthly alerts distribution, respectively. FIGS. 18 and 19 respectively show the total number of alert occurrences and the total number of alerts each month for every inverter used in this analysis.

In order to evaluate the performance of a suspected inverter, a Z-score comparison was implemented between a reference inverter and the suspected inverter. The Z-score, also known as the standard score, is calculated as the difference between a data point and the mean of the dataset, divided by the standard deviation of the dataset. Mathematically, it can be represented as: Z=(X−μ)/σ, where X is the data point, μ is the mean of the dataset, and σ is the standard deviation of the dataset. The result is a dimensionless quantity that describes how many standard deviations the data point is from the mean. One of the important properties of the Z-score is that it enables a comparison of data points from different datasets with different units of measurement. By standardizing the data, Z-scores can be used to compare data points from datasets with different scales and distributions. This is because the Z-score provides a standardized way of measuring deviation from the mean.

The Z-score is also useful in identifying outliers in a dataset. Outliers are data points significantly different from the other data points in the dataset. Z-scores can be used to detect outliers by comparing the Z-score of each data point with a predetermined threshold. With the Z-score of a data point, the probability of the data point occurring in the standard normal distribution can be determined. This can be useful in hypothesis testing and confidence interval estimation. It was assumed that inverters operating in similar environmental conditions should produce identical results. Thus, their Z-scores were compared to identify any significant discrepancies. The analysis was performed on 15 minutes of inverter output. The instances not following the reference inverter generation pattern were flagged as a fault; otherwise, the flag would be normal. A logistic regression, KNN, decision tree classification, and random forest were employed to predict the class of suspected malfunctioning inverters at any time. During the analysis, the power out of seven different inverters was analyzed for the past three months under the same weather conditions, including solar irradiance, ambient temperature, and humidity. The independent features were the Z-score of the reference inverter and the ratio of the Z-score of the suspected faulty inverter with respect to the reference inverter and the Z-score of the reference inverter. The reference inverter is the inverter that didn't show any sign of fault and has been performing without any alerts or alarms, and its output matches the irradiance pattern.

$${Z}_{ri} = \frac{{X}_{ri} - {μ}_{r}}{{σ}_{r}} \qquad ( 1 )$$

where Zᵣᵢ, Xᵣᵢ, μᵣ, σᵣ represent the Z-score, output at a particular instant, mean of the distribution, and standard deviation of the reference inverter output, respectively. With the method, it is easy to detect any anomaly in the inverter output; thus, it can help in predictive maintenance. Moreover, it can be very helpful in forecasting the health status of the inverter as it will determine the frequency of the flags over hours, days, and weeks, which can be a very good predictor of health status. FIG. 1 shows the implementation steps and ML model selection procedure for such problems.

The framework that was used initiated with the acquisition of data from the grid-connected solar PV system. This initial stage was followed by a preprocessing phase that encompasses the elimination or imputation of any missing values, along with the management of outliers. For both the reference inverter and the inverter under suspicion, the Z-scores were computed, and a subsequent comparison was conducted. If the score surpassed a predetermined threshold, it was classified as a fault; otherwise, it was marked as non-faulty. The analytical approach was executed in two distinct manners, one incorporating PCA and the other excluding PCA. In both scenarios, the framework commenced with the establishment of an empty array.

This was followed by the training of the model, and the accuracy of each model was consolidated into an accuracy array. Upon obtaining the accuracy metrics for both cases, the model demonstrating the highest accuracy was chosen for final implementation.

The utilization of PCA served to expedite the training process, as it has the capability to reduce the dimensionality of the data, thereby decreasing the training time. The dataset employed for the training encompassed a total of 22,283 instances.

Logistic regression is a statistical model that uses an equation to predict the likelihood of a binary result based on a set of input features. The equation used in logistic regression is called the logistic function, or sigmoid function, and is represented as shown in equation 2:

p=1/(1+e^{(-x)}) (2)

where p is the predicted probability of the binary outcome, e is the mathematical constant (~2.71828), and z is the linear combination of the input features and their as-sociated coefficients, also known as the logit. The calculation of z is shown in equation 3.

z=β₀+β₁x₁+β₂x₂+ . . . +βₙxₙ (3)

where β₀ represents the intercept, and β₁, β₂, . . . , βₙ are the coefficients associated with the input features x₁, x₂, . . . , xₙ, respectively.

The logistic function returns the probability on scale between 0 and 1. The predicted probability p can be interpreted as the likelihood of the binary outcome, with values closer to 0 indicating a lower probability and values closer to 1 indicating a higher probability. A maximum likelihood estimation method can be used to estimate the coefficients in the logistic regression equation, which involves finding the coefficients that maximize the likelihood of observing the binary outcome given the input features.

Maximum likelihood estimation (MLE) can be used to find the values of the parameters that maximize the likelihood of observing the data. The likelihood function L(θ|x) is defined as the probability of observing the data x given the parameters θ:

L(θ|x)=P(x|θ) (4)

where x is the observed data and θ is the vector of unknown parameters. The MLE of θ, denoted as θₕₐₜ, is the set of parameter values that maximize the likelihood function:

θₕₐₜ=argmax(L(θ|x)) (5)

MLE is calculated by taking the logarithm of the likelihood function to simplify the calculations and convert the product of probabilities into a sum of logarithms. This is called the log-likelihood function:

log L(θ|x)=Σ log P(xᵢ|θ) (6)

where the summation is taken over all data points. To find the maximum of the log-likelihood function, the derivative of the log-likelihood can be taken with respect to each parameter and set to zero. This gives a set of equations that can be solved numerically using optimization techniques. Once the maximum likelihood estimates of the parameters have been obtained, they can be used to make predictions or test hypotheses about the underlying distribution.

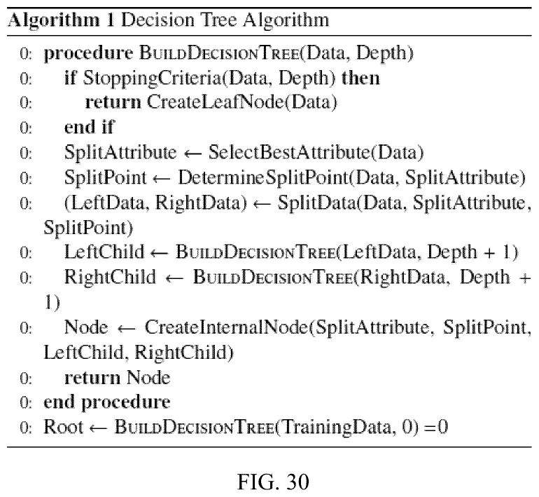

FIG. 30 shows a snippet of a decision tree algorithm. Decision trees use mathematical equations to determine the optimal split at each node. The two main equations used in decision trees are the Gini impurity and the information gain. The Gini impurity measures the probability of misclassifying a randomly chosen data point based on the distribution of classes in a set of data. The equation for Gini impurity is:

Gini=1−Σ(pᵢ)² (7)

where pᵢ is the ratio of data points with class i in the node. The information gain measures the reduction in entropy, or disorder, that results from splitting a set of data based on a particular feature. The equation for information gain is:

IG=entropyₚₐᵣₑₙₛ−mean(entropy_{children}) (8)

where entropy is a measure of the randomness in a set of data as shown in equation 9, and the weighted average is calculated based on the proportion of data points in each child node.

$$E = - {\sum }_{i = 1}^{n} {p}_{i} {log}_{2} ( {p}_{i} ) \qquad ( 9 )$$

In this equation, E is the entropy of the dataset, pᵢ is the proportion of the dataset belonging to class i. The sum is taken over all n classes in the dataset.

The decision tree algorithm uses these equations to determine the optimal split at each node, with the aim of maximizing in-formation gain or minimizing Gini impurity. By recursively splitting the data based on the feature that provides the most in-formation gain or the lowest Gini impurity, the algorithm builds a tree structure that can be used to classify new data points.

KNN is another classifier that is used in a wide variety of classification problems, including load forecasting, dynamic pricing, grid stability and fault detection. It is a non-parametric and instance-based algorithm, which means it doesn't make any assumptions about how the data is actually distributed. Instead, it uses the whole set of data to make forecasts. In KNN classification, the method works by figuring out how far apart a new data point is from every other data point in the set. Then, the “k” closest neighbors are chosen based on the shortest distances, and the new data point is put into the class that is most common among these neighbors. “k” is a hyperparameter whose value needs to be tuned for best performance. One of the advantages of the KNN classifier is that it is simple and easy to implement. It also does not require any training process, making it a good choice for small datasets. Additionally, it can handle non-linear decision boundaries and work well with numerical and categorical data. However, the KNN classifier has some limitations as well. It can be sensitive to the choice of distance metric and can perform poorly in high-dimensional feature spaces. Also, it can be hard to find the closest neighbors for big datasets because it takes a lot of processing power.

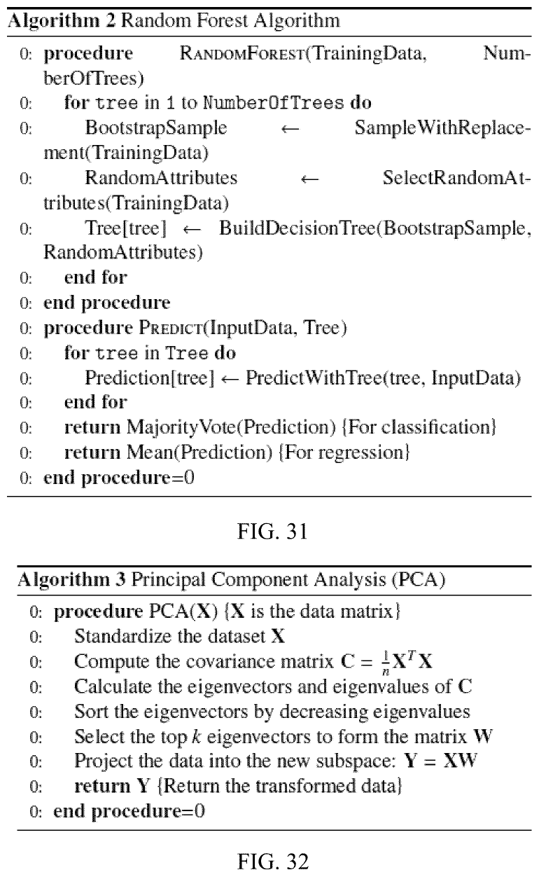

In random forest, the aggregation of multiple decision trees to make a final prediction is done through a process called averaging or voting, depending on the type of problem (classification or regression). FIG. 31 shows a random forest algorithm. For classification problems, the output of each decision tree is the predicted class label for the input data point. The predicted class label is then determined through a majority vote of all the decision trees. The equation for this process can be represented as:

ŷ=mode(T₁(x),T₂(x), . . . ,T_{N}(x)) (10)

where ŷ is the predicted class label for the input data point x, T₁ to T_{N} is the individual decision trees, and mode represents the most frequently occurring class label among the predictions of all the decision trees.

FIG. 32 shows a PCA algorithm. PCA is a statistical methodology used to decrease the dimensionality of a dataset while endeavoring to preserve the maximum amount of the original variability. The fundamental concept of PCA is the identification of the directions that exhibit the highest variation within the dataset. Subsequently, the data is projected onto a subspace of reduced dimensions, which is determined by these identified directions. PCA works by finding a set of orthogonal vectors, called principal components, that represent the directions of maximum variance in the data. The first principal component explains the most variation in the data, and each subsequent component explains as many variations as feasible. A common rule of thumb is to select the number of components that explain 80-90% of the total variation in the data when determining the number of principal components. After identifying the principal components, the initial data can be projected onto the lower-dimensional subspace defined by these components. This generates a new set of variables, known as the principal component scores, that represent the data variation in a more compact manner. PCA is beneficial for a variety of applications, such as data visualization, feature extraction, and data compression. By reducing the dimensionality of the data, complex datasets can be simpler to analyze and interpret, and the risk of overfitting in machine learning models can be reduced.

The evaluation metrics were true positive (TP), true negative (TN), false positive (FP), false negative (FN), accuracy, precision, recall, and F1 score. These terms will now be discussed as they are used and understood in the fields of statistics and ML (for TP, TN, FP, and FN) and in the field of ML (for accuracy, precision, and recall). The term “true positive” refers to correct classification of a positive instance by a model or classifier. This means that the model correctly identifies a particular example as belonging to the class that is being considered as “positive”. The term “true negative” is a term used to describe a situation in which a model or classifier correctly identifies a negative instance. In other words, a true negative occurs when the model correctly predicts that a particular example does not belong to the class that is being considered as “positive”. The term “false positive” is a term used to describe a situation in which a model or classifier incorrectly identifies a positive instance. In other words, a false positive occurs when the model predicts that a particular example belongs to the class that is being considered as “positive”, but in reality, it does not. The term “false negative” is a term used to describe a situation in which a model or classifier incorrectly identifies a negative instance. In other words, a false negative occurs when the model predicts that a particular example does not belong to the class that is being considered as “positive”, but in reality, it does.

Accuracy is a metric used to evaluate the performance of a classification model. It measures the percentage of correctly predicted labels (both positive and negative) out of all the labels in the dataset. To calculate accuracy, the number of correctly classified instances is divided by the total number of instances in the dataset. Mathematically, accuracy is defined as follows:

$$Accuracy = \frac{TP + TN}{TP + TN + FP + FN} \qquad ( 11 )$$

While accuracy is a simple and intuitive metric, it has some limitations, especially when dealing with imbalanced datasets, where one class has a much larger number of instances than the other. In such cases, accuracy can be misleading, as a model that always predicts the majority class will have high accuracy, even if it fails to detect all instances of the minority class.

Therefore, it is often useful to use other metrics in conjunction with accuracies, such as precision, recall, and F1 score, to gain a more complete understanding of the performance of a classification model.

Precision serves as a criterion for assessing the capability of a classification model, particularly in its potential to accurately detect positive instances. Precision calculates the proportion of correct positive predictions among the total positive predictions formulated by the model.

The precision formula is:

$$Precision = \frac{TP}{TP + FP} . \qquad ( 12 )$$

Recall is a key indicator used to appraise the performance of a classification model, specifically in terms of its competence in correctly recognizing positive classifications. It is expressed as the ratio of true positive predictions to the sum of genuine positive occurrences within the data collection.

The recall formula is:

$$Recall = \frac{TP}{TP + FN} \qquad ( 13 )$$

The metric of recall is crucial, especially when there are significant implications for false negatives (i.e., when the full detection of positive cases is essential, even if it leads to some negative cases being incorrectly labeled as positive). However, for a more nuanced assessment of a classification model's performance, recall should not be considered in isolation. It should be accompanied by other metrics, such as precision, to provide a more comprehensive evaluation of the model's efficacy.

The F1 score is a metric used to evaluate the performance of a classification model, which takes both precision and recall into account. The F1 score is the harmonic mean of precision and recall, and it provides a single score that balances the two metrics. The F1 score formula is:

$$F {1}_{Score} = 2 \frac{Precision * Recall}{Precision + Recall} \qquad ( 14 )$$

Precision is a measure that evaluates the ratio of correct positive predictions to the overall number of positive predictions made by the algorithm. On the other hand, recall calculates the proportion of accurately predicted positive instances against the total quantity of real positive cases present in the dataset.

The F1 score is a metric that ranges between 0 and 1, where a score of 1 represents the highest achievable performance. A high F1 score is indicative of a model that exhibits both precision, characterized by a low number of false positives, and recall, characterized by a low number of false negatives. A low F1 score suggests that the model exhibits imprecision, a high incidence of false positives, or low recall, accompanied by a high occurrence of false negatives.

The F1 score is a useful metric for comparing the performance of different classification models, especially when the dataset is imbalanced or false positives and negatives have different costs. It provides a more complete picture of the model's performance than precision or recall alone.

A graphic representation called an AUC (area under the curve) curve, also known as the ROC (receiver operating characteristic) curve, can be used to evaluate the effectiveness of a classification model. This is a plot of the true positive rate (sensitivity) against the false positive rate (i.e., one minus specificity, or 1−specificity) at a number of different threshold values. The AUC or ROC can be used when working with unbalanced datasets or determining the best threshold for a classifier.

The area under the ROC curve, often known as the AUC value, may vary ranging from 0 to 1. It gives a single number that may be used to summarize the performance of the classifier over all of the available thresholds. A better-performing model is indicated by an AUC value that is greater. An AUC=0.5 indicates that the classifier is not any more accurate than random guessing. It is unable to differentiate between the positive and negative classes in any meaningful way. An AUC≥0.5 means that the classifier is more accurate than taking a random guess. If the AUC value is larger, it suggests that the capacity to differentiate between the positive and negative classifications is stronger as well. An AUC=1 indicates that the classifier has perfect discriminating power because it is able to distinguish between the positive and negative classes flawlessly. Because of these reasons, the AUC curve is beneficial in classification problems. First, it provides an all-encompassing perspective of the classifier's capacity by taking into account how well the model performs at each and every conceivable threshold. Second, due to the fact that it takes into consideration both sensitivity and specificity, it is not affected by datasets that are not evenly distributed. Third, it is possible to use it to compare several classifiers by comparing the AUC values that they produce, which can assist in determining which model is the most effective solution to a certain problem. Fourth, the point on the ROC curve closest to the upper-left corner, which reflects the optimal balance between sensitivity and specificity, may be used to determine the appropriate threshold for the classifier.

The classification model was trained and evaluated using a seven grid-connected solar inverters dataset. This data is of 5-minute time intervals for three months. To evaluate the efficacy of the ML model, the technique of 5-fold cross-validation was utilized. This method involves slicing the dataset into five sections of equal size, each serving as a validation set once. In comparison, the other four sections are used for training purposes. This procedure was performed five times, with each fold serving as the validation set just a single time; the model's effectiveness was assessed by taking the over-all average of the results obtained from all five folds. The following evaluation metrics were used-accuracy, precision, recall, and F1 score. The formulation of these metrics is presented in equations 11, 12, 13, and 14, respectively.

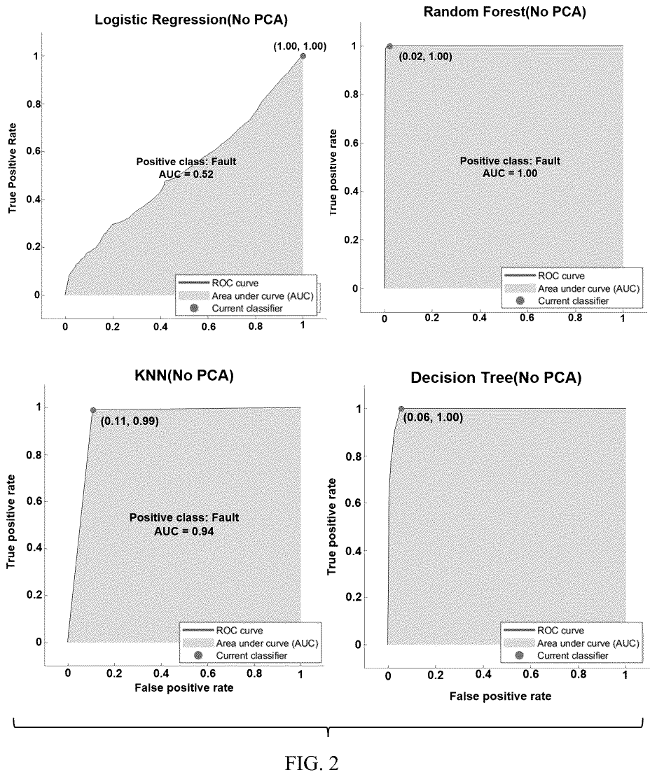

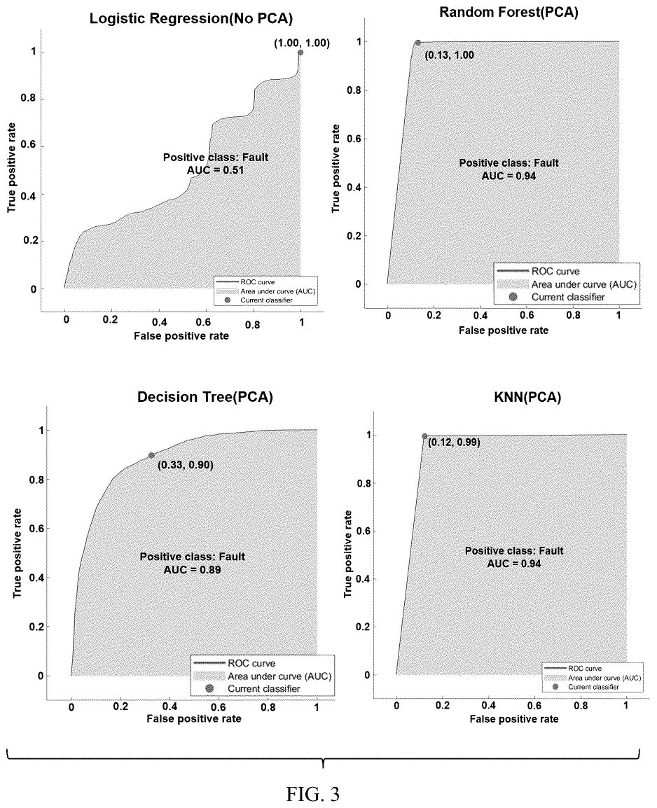

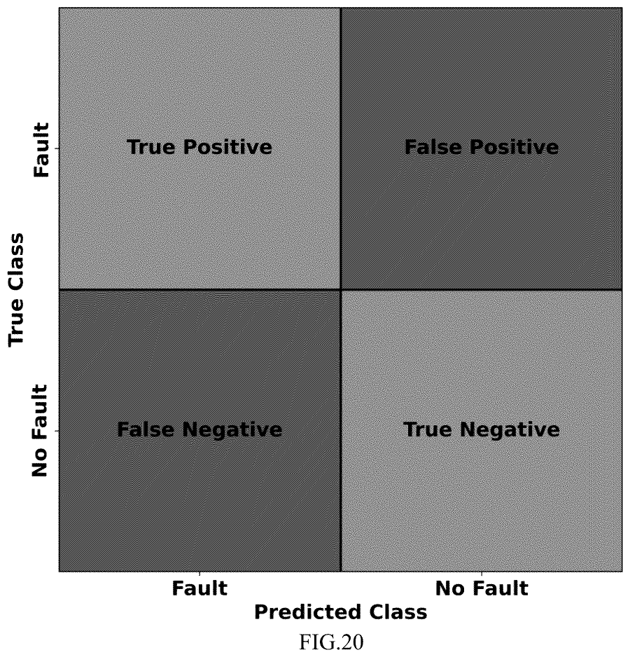

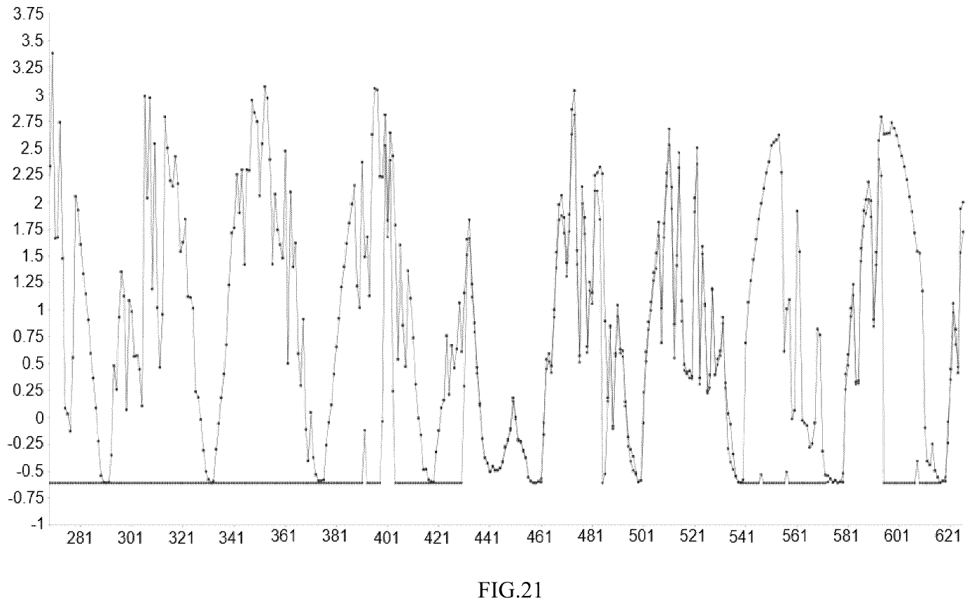

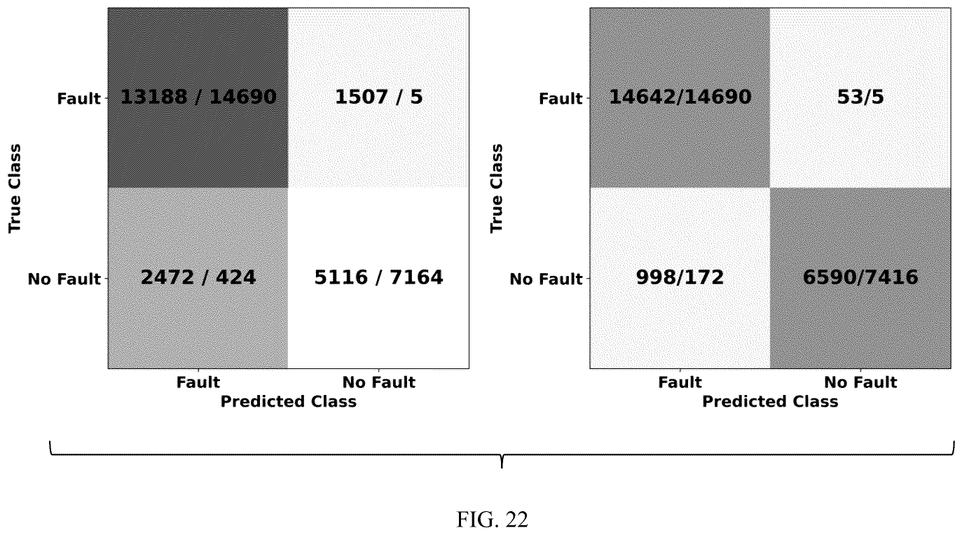

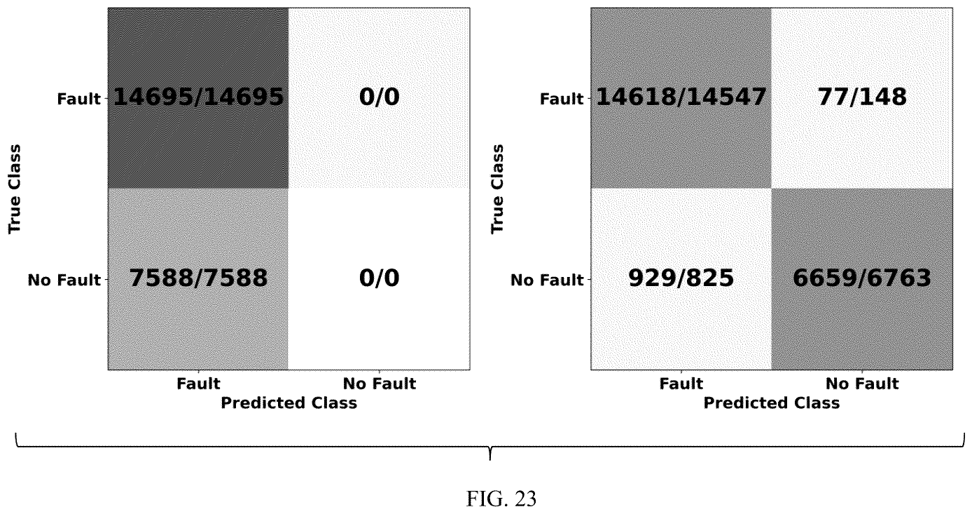

FIG. 21 shows a plot of intermittency in performance. FIG. 2 shows AUC/ROC curves for the logistic regression, random forest, KNN, and decision tree, all with no PCA; and FIG. 3 shows AUC/ROC curves for the logistic regression, random forest, KNN, and decision tree, all with PCA. FIG. 22 shows the decision tree confusion matrix (left) and the random forest confusion matrix (right); and FIG. 23 shows the logistic regression confusion matrix (left) and the KNN confusion matrix (right). For reference, FIG. 20 shows the layout of a confusion matrix.

Both with and without PCA, the random forest-based model's performance was superior to that of existing classifiers. The non-PCA model yielded an accuracy of 99.21%, precision of 99.99%, recall of 98.84%, and an F1 score of 99.40%. These findings prove that the model has high accuracy and maintains an appropriate balance between precision and recall. In addition, a comparison with the performance of logistic regression, decision tree, and KNN demonstrated that the random forest-based technique is more effective than the others. The logistic regression model performed the worst as it predicted all the classes as a fault. After the random forest regressor, the second best model was the decision tree, with an accuracy of 98.1%. However, after the application of PCA, its performance deteriorated significantly, with an accuracy of only 82.1%. The accuracy remained almost constant (about 95.5%) for KNN both with PCA and without PCA.

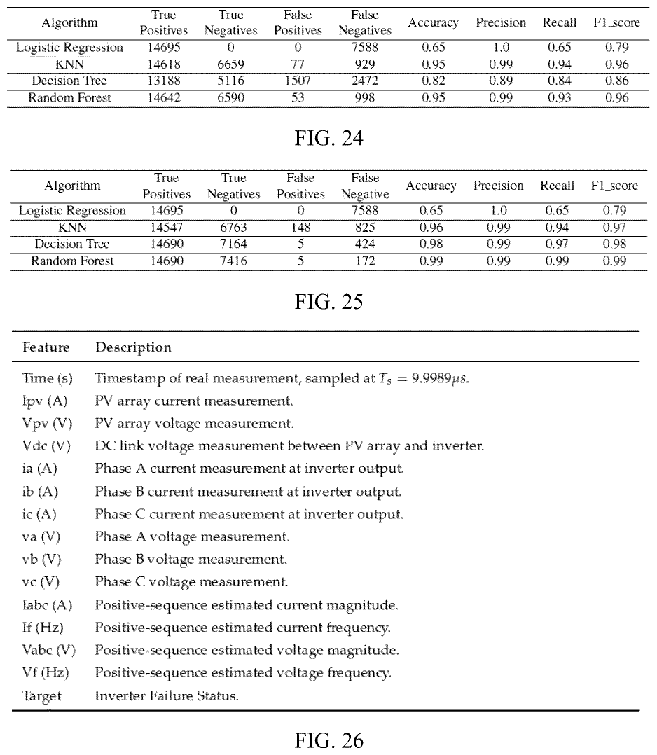

The table in FIG. 24 shows the accuracy of each model with the inclusion of PCA, and the table in FIG. 25 shows the accuracy of each model without PCA. FIGS. 22 and 24 show that the decision tree with PCA could predict 13188 instances of faults correctly and 5116 cases when there was no fault. FIG. 25 shows that, without PCA, decision tree correctly classified 14690 instances of true positives and 7164 instances of true negatives. The random forest confusion matrix in FIG. 22 shows that this (with PCA) performed better than the decision tree with 14642 and 6590 instances of faults and no-fault, respectively. Without PCA, random forest correctly classified 14690 instances of true positives and 7416 instances of true negatives giving overall accuracy of 99.99% (FIG. 25).

Referring to the confusion matrixes for logistic regression and KNN (FIG. 23) it can be seen that logistic regression was incapable of exacting any knowledge from the data (with or without PCA), as it classified all the classes as a fault. With PCA the performance of KNN was very similar to a random forest with 14642 true positives and 6590 true negatives. Though, without PCA, KNN didn't perform as well compared to the random forest, giving 14547 true positives and 6763 true negatives.

Using actual data from the PV power plant at Florida International University (FIU), this analysis was able to effectively show the creation and implementation of a complete fault detection and classification system for grid-connected single-phase PV inverters. The system/method of embodiments of the subject invention showed its efficiency and dependability in identifying and classifying failure scenarios in solar inverters. Random forest beat the other approaches, achieving an accuracy of 99.2% without PCA and an accuracy of 95.3% when PCA was included. Due to its high degree of precision, the approach is a perfect option for assuring the stability and dependability of green energy systems, particularly grid-connected PV inverters.

### Example 2

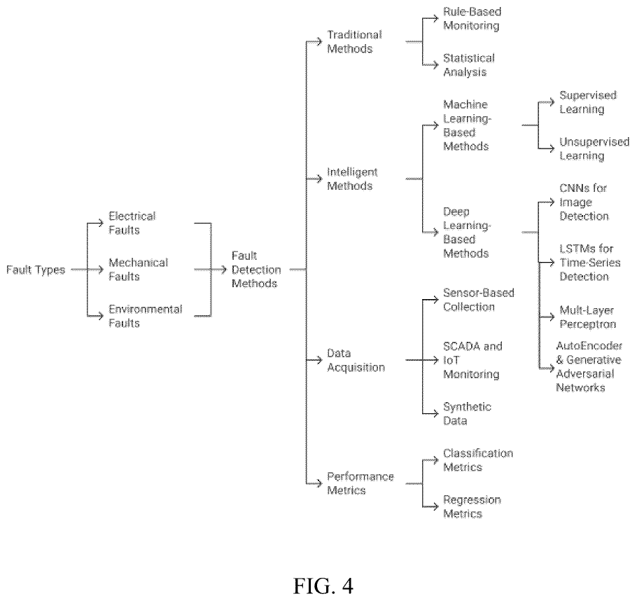

The framework shown in FIG. 1 was used to evaluate the performance of inverters. FIG. 4 shows types of faults and the detection methods adopted. To assess the performance of ML models (including decision tree, KNN, logistic regression, and random forest), lab-generated open-source data from a third-party source was utilized. The dataset utilized in this analysis is derived from experimental fault scenarios in grid-connected PV systems operating under both maximum power point tracking (MPPT) and intermediate power point tracking (IPPT) modes. The dataset, known as GPVS-Faults, was obtained from laboratory experiments that systematically introduced faults into a PV system, including inverter faults and insulated-gate bipolar transistor (IGBT) failures, among other fault types.

These experimentally generated faults provide reliable, realistic data suitable for training and validating fault detection algorithms aimed at inverter protection and predictive maintenance tasks (see also, e.g., Bakdi et al., GPVS-Faults: Experimental Data for fault scenarios in grid-connected PV systems under MPPT and IPPT modes, 2020, doi:10.17632/n76t439f65.1; which is hereby incorporated by reference herein in its entirety). The table in FIG. 25 presents a list of the features in the dataset. FIG. 6 shows correlations between input features and the target variable for inverter fault detection. The most strongly correlated features with the target are Vₚᵥ (0.72 positive correlation) and Iₚᵥ (−0.51 negative correlation), indicating these variables significantly impact fault prediction. Features such as I_{abc} also exhibit a moderate negative correlation (−0.49).

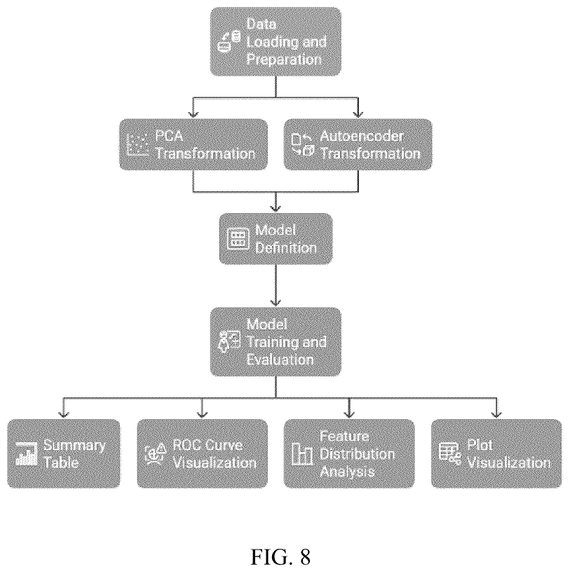

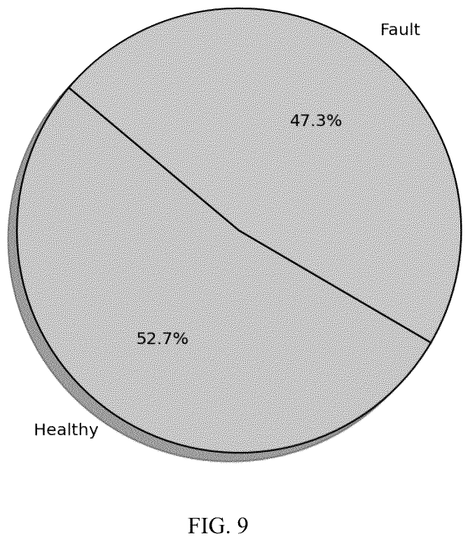

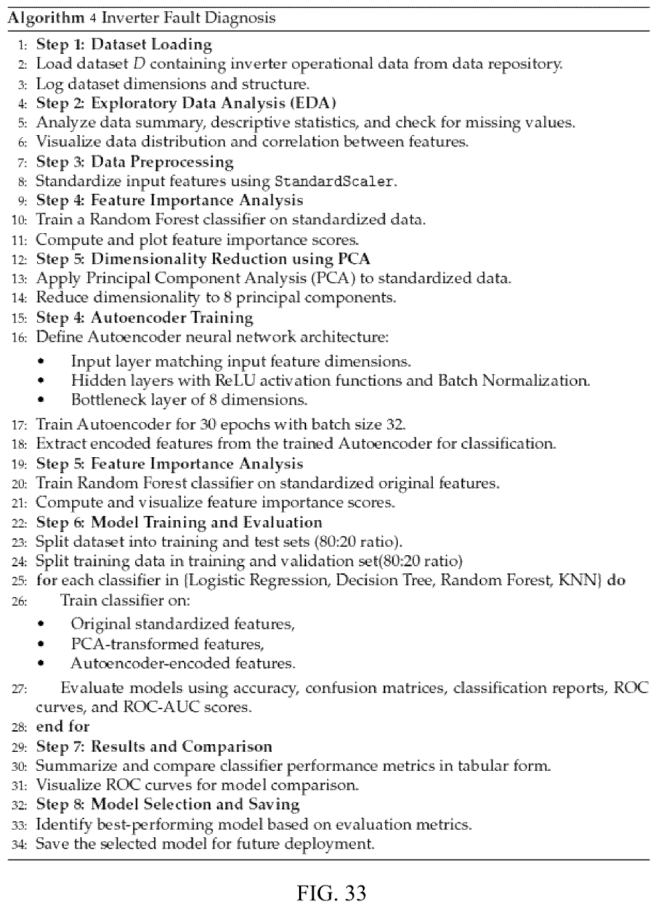

This analysis presents a comprehensive methodology aimed at evaluating and comparing the effectiveness of various ML algorithms for the classification of inverter faults using binary inverter data. The dataset includes a total record of 272,727 with 15 features including the target. Out of the total records there are 143,715 (52.7%) instances of healthy and 129,012 (47.3%) instances of fault, as shown in FIG. 9. The overarching approach includes several distinct steps: data preparation; feature engineering through standardization; dimensionality reduction using PCA; feature extraction through an autoencoder neural network; model training and validation; and performance evaluation using key metrics and visualization techniques. The methodology is summarized in FIG. 8 and the algorithm shown in FIG. 33.

The initial phase involved loading of the dataset for preprocessing and initial data analysis. The dataset included a series of features and a binary target variable indicating the presence or absence of inverter faults, as shown in the table in FIG. 25. Following data loading, the independent features and target variables were separated, facilitating independent analysis and pre-processing. The independent numerical variables in the dataset were then standardized using the StandardScaler from scikit-learn. The scaling can be an important step in ensuring that each feature contributes equally to the model training by normalizing the distribution of each variable.

In the next step, the standardized data was split into training, validation, and testing subsets by applying the train-test split strategy. In the first split process the dataset was split into an 80% training set and a 20% testing set. The training subset was further split into training and validation subsets, comprising 80% and 20% of the initial training data, respectively. This multi-step splitting allowed for effective model training, hyperparameter tuning, and unbiased evaluation on unseen test data and avoided overfitting.

During the training phase, random forest, logistic regression, decision tree, and KNN were employed. Initial training was performed using the entire standardized feature set.

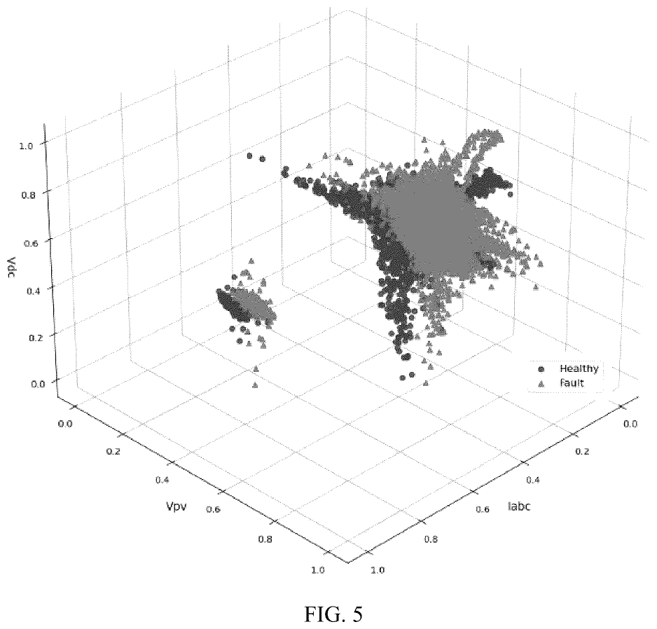

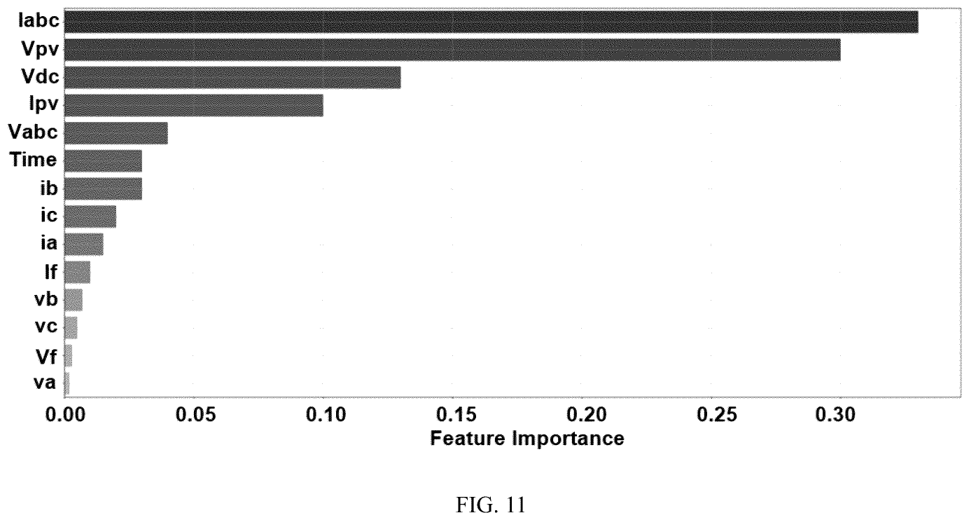

In the first training, all the features were used during training to detect the fault. Following the first phase of the training, a feature importance analysis was performed to analyze the contribution of each feature in correctly classifying the target label, as shown in FIG. 11; and FIG. 5 shows a scatter plot of the top three features (V_{dc}, Vₚᵥ, and I_{abc}). PCA was also used to reduce dimensionality and improve performance and computational efficiency. The PCA transformation aimed at reducing the feature space to eight principal components, retaining maximum data variance in the data without losing important information. This procedure resulted in new derived feature sets, subsequently used to retrain the machine learning models. The transformed data underwent identical partitioning strategies as previously described, ensuring a consistent framework for comparison.

Moreover, an advanced autoencoder-based feature extraction method was introduced to explore a deep learning-based dimensionality reduction technique. The autoencoder network architecture comprised an input layer corresponding to the standardized feature set's dimensionality, an intermediate dense layer with 32 neurons utilizing a rectified linear unit (ReLU) activation function, followed by a batch normalization layer to stabilize learning. This was followed by an encoding layer compressing features down to eight dimensions. The decoding process mirrored the encoding pathway but aimed at reconstructing the original input. The autoencoder was trained using 30 epochs with batch sizes of 32 and a mean-squared error loss function. Upon training completion, the encoded features were extracted and employed as inputs for retraining the selected machine learning classifiers.

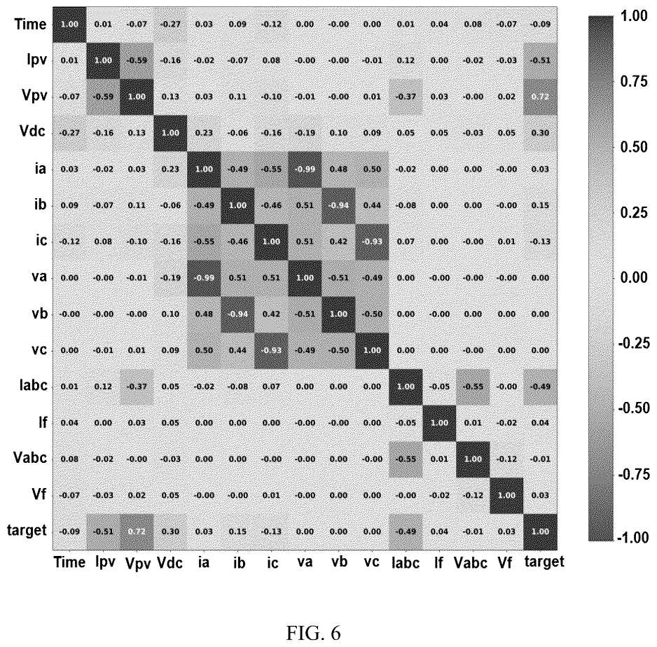

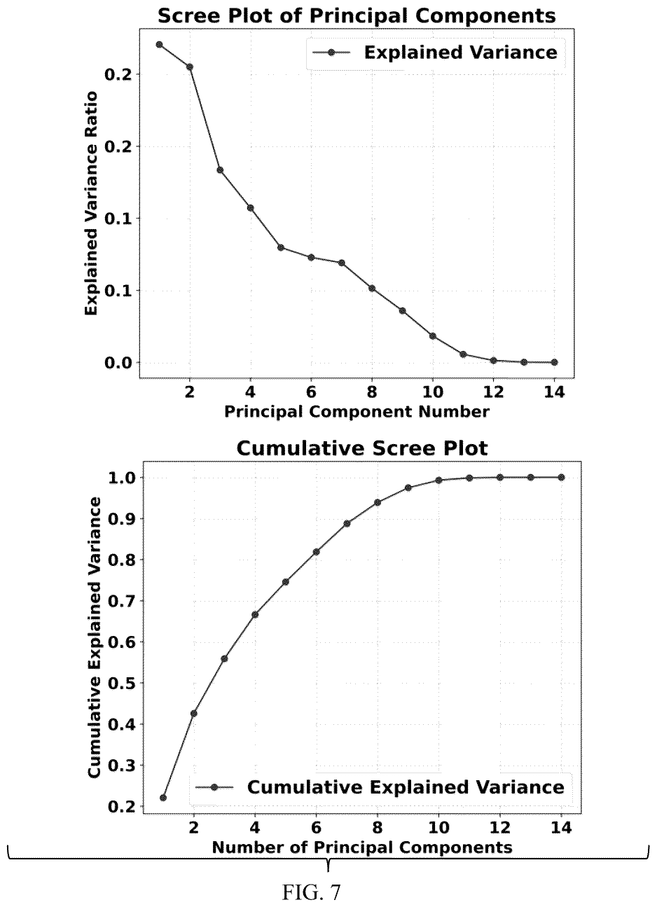

For each transformation method-standardized features, PCA-transformed features derived using scree plot analysis as shown in FIG. 7, and autoencoder-extracted features-four ML models (random forest, logistic regression, decision tree, and KNN) were systematically trained and evaluated. The random forest classifier, with 100 estimators, leveraged ensemble learning to mitigate overfitting and capture complex feature interactions. Logistic regression, configured to execute binary classification with a maximum iteration limit set to ensure convergence, provided insights into linear relationships within the data. Decision tree classification offered intuitive model interpretability, and KNN, with k=5, utilized proximity-based classification to identify patterns in the transformed feature spaces.

Key performance indicators included accuracy, confusion matrices, classification reports detailing precision, recall, and F1-scores, and the computation of the ROC curve along with the AUC score. The ROC analysis was particularly insightful, providing a comprehensive view of the trade-off between true positive rates and false positive rates across varying classification thresholds.

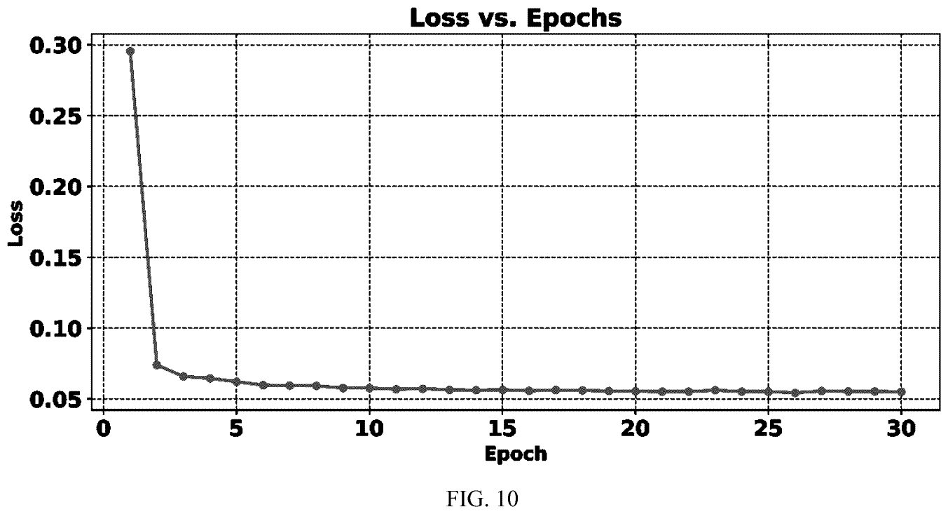

Further, the autoencoder employed for feature extraction was carefully validated by analyzing training convergence through epochs to ensure the stability of the encoding process. The training of the autoencoder spanned 30 epochs with a batch size of 32, with the optimizer effectively adjusting the model parameters iteratively to minimize reconstruction error, thus ensuring the robustness of the extracted features. FIG. 10 shows the variation of the loss with respect to epochs during autoencoders training. Detailed visualizations significantly enhanced the interpretability of the results. Confusion matrices were generated for each model, clearly illustrating the distinction between true positives, false positives, true negatives, and false negatives. These visual tools were instrumental in diagnosing the strengths and limitations of each model with respect to classification accuracy and types of errors made.

Further enriching the analytical depth, the ROC curves for each model provided graphical representations of their discriminative capabilities, showcasing sensitivity (true positive rate) against specificity (false positive rate). These curves, supplemented by the numerical AUC scores, facilitated straightforward comparisons among models, underscoring their relative performances and their predictive capabilities in handling binary inverter fault classification tasks.

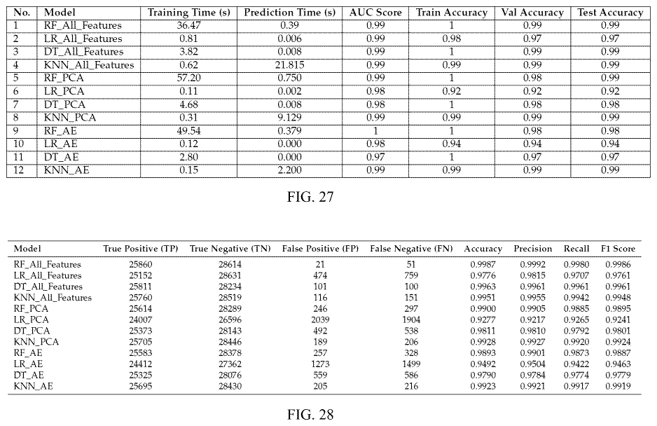

The comparative study of dimensionality reduction methods for inverter fault detection in GCPVS's yielded a comprehensive evaluation of various ML models, both with and without dimensionality reduction techniques. The experimental results are summarized in the tables in FIGS. 27 and 28, which present the performance metrics of the models in terms of training time, prediction time, AUC score, accuracy across training, validation, and test sets, as well as detailed classification metrics including TP, TN, FP, FN, accuracy, precision, recall, and F1 score. These metrics collectively provide insight into the effectiveness and efficiency of the random forest, logistic regression, decision tree, and KNN when applied to the original feature set (All Features), PCA-reduced features, and autoencoder (AE)-reduced features. The performance and accuracy metrics of the models are summarized in the tables in FIGS. 27 and 28, respectively.

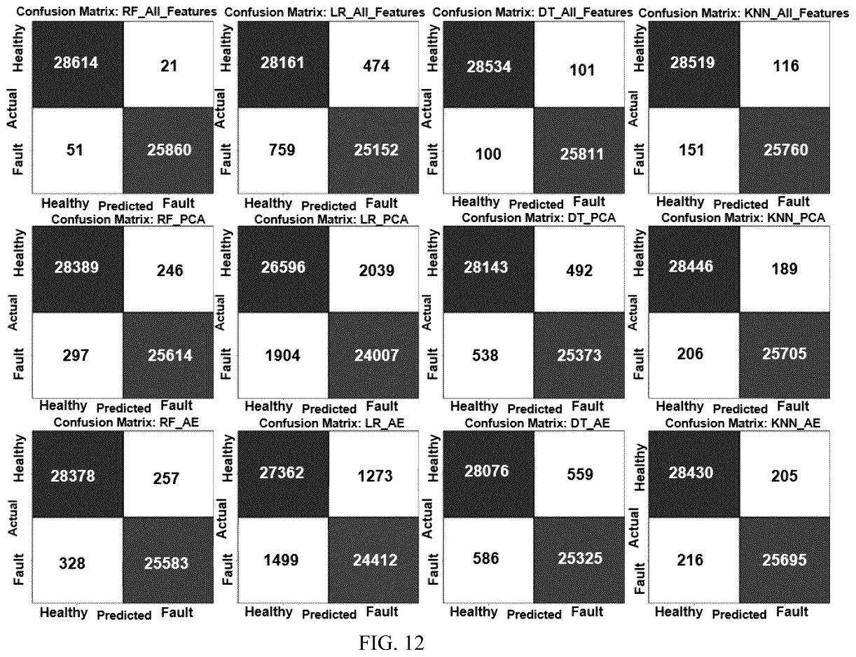

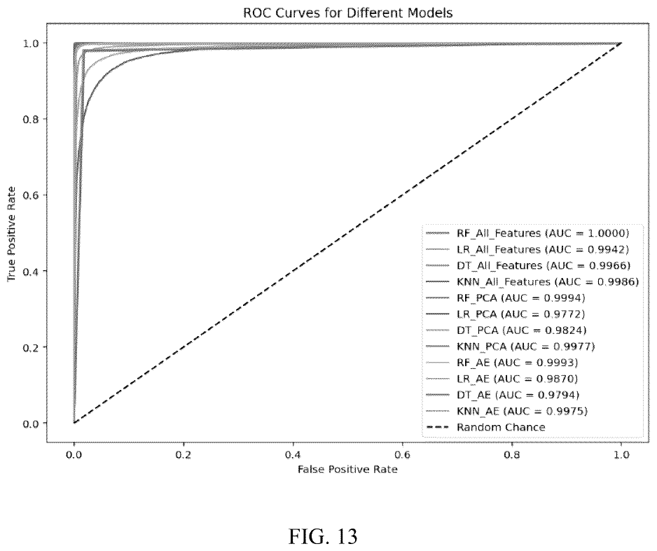

FIG. 12 shows confusion matrixes for all models, and FIG. 13 shows ROC curves for the different models. In FIG. 12, from left to right and then top to bottom, the confusion matrixes are for: random forest with all features; logistic regression with all features; decision tree with all features; KNN with all features; random forest with PCA; logistic regression with PCA; decision tree with PCA; KNN with PCA; random forest with AE; logistic regression with AE; decision tree with AE; and KNN with AE. Each confusion matrix in FIG. 12 has actual on the vertical axis, with healthy being the top row and fault being the bottom row, and then predicted on the horizontal axis, with healthy being the left column and fault being the right column.

The baseline performance of the models utilizing the full feature set demonstrated high predictive accuracy and robustness across all classifiers. As shown in the table in FIG. 27, the random forest with all features model achieved the highest test accuracy of 0.99, with a training time of 36.47 seconds and a prediction time of 0.39 seconds. The AUC score of 0.99 further corroborates its excellent discriminative ability. Detailed results in the table in FIG. 28 indicate an accuracy of 0.9987, with a precision of 0.9992, recall of 0.9980, and F1 score of 0.9986. The model correctly identified 25,860 TP and 28,614 TN instances, with only 21 FP and 51 FN, highlighting its superior performance in minimizing misclassifications.

The logistic regression with all features model, while computationally efficient with a training time of 0.81 seconds and a prediction time of 0.006 seconds, exhibited a slightly lower test accuracy of 0.97. Its AUC score remained high at 0.99, but the classification metrics in the table in FIG. 28 reveal a drop in performance, with an accuracy of 0.9776, precision of 0.9815, recall of 0.9707, and F1 score of 0.9761. The increase in FP (474) and FN (759) suggests that logistic regression struggled to capture the full complexity of the data compared to random forest.

The decision tree with all features model performed comparably to random forest, with a test accuracy of 0.99, a training time of 3.82 seconds, and a prediction time of 0.008 seconds. Its AUC score of 0.99 and classification metrics (accuracy of 0.9963, precision of 0.9961, recall of 0.9961, and F1 score of 0.9961) indicate strong performance, though it recorded slightly higher FP (101) and FN (100) than random forest with all features. The KNN with all features model, despite its high test accuracy of 0.99 and AUC score of 0.99, incurred a significant computational cost during prediction, with a time of 21.815 seconds. This is likely due to the distance computation required for all features in the original high-dimensional space. Its classification metrics (accuracy of 0.9951, precision of 0.9955, recall of 0.9942, and F1 score of 0.9948) were slightly lower than random forest and decision tree, with 116 FP and 151 FN.

Applying PCA as a dimensionality reduction technique resulted in varied impacts on model performance. The random forest-based PCA model maintained a high test accuracy of 0.99 and an AUC score of 0.99, though its training time increased to 57.20 seconds, likely due to the additional computational overhead of PCA transformation. Prediction time rose to 0.750 seconds, reflecting a trade-off between dimensionality reduction and inference speed. The table in FIG. 28 shows an accuracy of 0.9900, precision of 0.9905, recall of 0.9885, and F1 score of 0.9895, with 246 FP and 297 FN, indicating a slight decline in classification performance compared to random forest with all features.

The logistic regression-based PCA model exhibited the most significant reduction in performance, with a test accuracy of 0.92 and an AUC score of 0.98. Its training and prediction times were notably low (0.11 seconds and 0.002 seconds, respectively), making it the most computationally efficient model in this category. However, its classification metrics (accuracy of 0.9277, precision of 0.9217, recall of 0.9265, and F1 score of 0.9241) reflect a substantial increase in FP (2039) and FN (1904), suggesting that PCA may have discarded critical features necessary for effective fault detection with logistic regression.

The decision tree-based PCA model retained a test accuracy of 0.98 and an AUC score of 0.98, with a training time of 4.68 seconds and a prediction time of 0.008 seconds. Its classification metrics (accuracy of 0.9811, precision of 0.9810, recall of 0.9792, and F1 score of 0.9801) indicate a modest decline from the decision tree with all features, with 492 FP and 538 FN, suggesting that PCA preserved most of the decision tree's discriminative power.

The KNN-based PCA model benefited significantly from dimensionality reduction, reducing its prediction time to 9.129 seconds while maintaining a test accuracy of 0.99 and an AUC score of 0.99. Its classification metrics (accuracy of 0.9928, precision of 0.9927, recall of 0.9920, and F1 score of 0.9924) improved slightly compared to KNN with all features, with 189 FP and 206 FN, demonstrating that PCA effectively reduced computational complexity without compromising accuracy.

The use of an AE for dimensionality reduction produced results that were generally competitive with PCA, with some notable differences. The random forest-based AE model achieved a test accuracy of 0.98 and an AUC score of 1.00, with a training time of 49.54 seconds and a prediction time of 0.379 seconds. Its classification metrics (accuracy of 0.9893, precision of 0.9901, recall of 0.9873, and F1 score of 0.9887) indicate robust performance, though slightly below random forest with all features, with 257 FP and 328 FN.

The logistic regression-based AE model showed a test accuracy of 0.94 and an AUC score of 0.98, with exceptionally low training and prediction times (0.12 seconds and 0.000 seconds, respectively). However, its classification metrics (accuracy of 0.9492, precision of 0.9504, recall of 0.9422, and F1 score of 0.9463) reflect a higher error rate, with 1273 FP and 1499 FN, suggesting that the AE may not have captured the linear relationships as effectively as PCA for logistic regression.

The decision tree-based AE model recorded a test accuracy of 0.97 and an AUC score of 0.97, with a training time of 2.80 seconds and a prediction time of 0.000 seconds. Its classification metrics (accuracy of 0.9790, precision of 0.9784, recall of 0.9774, and F1 score of 0.9779) indicate a slight decline from decision tree with all features, with 559 FP and 586 FN, reflecting a minor loss of discriminative capability.

The KNN-based AE model achieved a test accuracy of 0.99 and an AUC score of 0.99, with a training time of 0.15 seconds and a prediction time of 2.200 seconds. Its classification metrics (accuracy of 0.9923, precision of 0.9921, recall of 0.9917, and F1 score of 0.9919) were comparable to KNN-based PCA, with 205 FP and 216 FN, demonstrating that the AE effectively reduced dimensionality while preserving KNN's performance.

Across all configurations, random forest consistently outperformed other models in terms of accuracy, precision, recall, and F1 score, particularly when using the full feature set. Dimensionality reduction with PCA and AE maintained high accuracy for random forest and KNN, though with minor tradeoffs in classification performance and increased training times. Logistic regression exhibited the greatest sensitivity to dimensionality reduction, with significant drops in accuracy and increases in misclassifications, suggesting that it relies heavily on the original feature space. Decision tree showed moderate resilience to both PCA and AE, with slight reductions in performance metrics.

In terms of efficiency, PCA and AE significantly reduced prediction times for KNN, making it a more practical choice for real-time applications despite its high computational cost in the original feature space. Logistic regression remained the fastest model across all configurations, though its lower accuracy limits its suitability for critical fault detection tasks. Random forest, while computationally intensive during training, offered a balanced tradeoff between accuracy and inference speed, particularly with AE.

The results demonstrate that dimensionality reduction techniques such as PCA and AE can effectively reduce computational complexity while maintaining high accuracy for inverter fault detection in grid-connected solar PV systems. Random forest with the full feature set emerged as the most accurate model, though KNN with PCA or AE offers a compelling alternative for scenarios prioritizing efficiency. These findings provide valuable insights for optimizing fault detection systems in renewable energy applications, balancing accuracy, and computational resources effectively.

Overall, random forest consistently outperformed other models across all feature extraction techniques, achieving exceptional accuracy and near-perfect AUC scores. Specifically, random forest with the complete original feature set reached an impressive accuracy of 99.87% and an AUC score of approximately 0.99, emphasizing its superior capacity to model complex interactions between features. However, this high performance comes at the cost of increased computational demands during training. Despite longer training durations (ranging up to 57.20 seconds with PCA), its inference speed remained practical for real-world applications.

Logistic regression exhibited the fastest computational performance, with minimal training times (0.11-0.81 seconds) and near-instantaneous inference. While logistic regression with original features retained high accuracy (approximately 97.76%), its performance decreased notably after dimensionality reduction with PCA (accuracy dropping to 92.77%). Interestingly, employing AE-derived features significantly boosted LR's accuracy (94.92%), demonstrating the value of autoencoder-based nonlinear transformations.

The decision tree provided a strong balance between computational efficiency and accuracy. Decision tree models trained on original features maintained excellent accuracy (99.63%) and rapid inference speed, making them especially suitable for real-time prediction environments. Their performance slightly diminished when PCA or AE-derived features were used, highlighting the decision tree's sensitivity to transformed features.

KNN demonstrated robust accuracy (approximately 99%) but experienced substantial computational overhead during inference due to intensive distance computations. Dimensionality reduction significantly improved its inference time, particularly with autoencoder-extracted features, which dropped inference duration dramatically (from 21.82 seconds to 2.20 seconds), indicating that AE-derived features effectively preserve essential data characteristics for proximity-based classifiers.

The analysis underscores the value of dimensionality reduction techniques, particularly AEs, for balancing model performance with computational efficiency, which is essential for deploying predictive systems in resource-constrained environments. Ultimately, model selection should align explicitly with operational priorities: random forest is optimal when accuracy is paramount; decision tree and KNN with AE-derived features are ideal for real-time inference; and logistic regression with AE-derived features is recommended for applications demanding extreme computational efficiency with acceptable accuracy.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

What is claimed is:

1. A system for monitoring inverters for faults, the system comprising:
a plurality of inverters;
a processor in operable communication with the plurality of inverters; and
a machine-readable medium in operable communication with the processor and having instructions stored thereon that, when executed by the processor, perform the following steps:
i) receiving data from the plurality of inverters;
ii) performing preprocessing on the data received from the plurality of inverters to give preprocessed data;
iii) calculating a Z-score for each inverter of the plurality of inverters using the preprocessed data, the Z-score being a measure of how far away a value for the respective inverter of an inverter property is from an expected mean value for the inverter property;
iv) upon the Z-score for a respective inverter being at or below a predetermined threshold, determining that the respective inverter is operating normally;
v) upon the Z-score for a respective inverter exceeding the predetermined threshold, determining that a fault exists with the respective inverter;
vi) utilizing a machine learning (ML) model on the preprocessed data and the Z-scores for the plurality of inverters to determine if a fault exists in any inverter of the plurality of inverters; and
vii) generating an alert for any inverter of the plurality of inverters determined to have a fault.

2. The system according to claim 1, the ML model being a trained ML model.

3. The system according to claim 1, the ML model being random forest, decision tree, K-Nearest Neighbor (KNN), or logistic regression.

4. The system according to claim 1, the ML model being random forest.

5. The system according to claim 1, step vi) comprising using principal component analysis (PCA) on the preprocessed data before utilizing the ML model.

6. The system according to claim 1, step vi) comprising using an autoencoder (AE) on the preprocessed data before utilizing the ML model.

7. The system according to claim 1, the performing of the preprocessing comprising removing outliers in the data, removing duplicates in the data, and interpolating missing datapoints in the data.

8. The system according to claim 1, the instructions when executed further comprising:
viii) shutting down any inverter of the plurality of inverters determined to have a fault to allow for maintenance on said inverter.

9. The system according to claim 8, the instructions when executed further comprising:
ix) repeating steps i)-viii) at regular time intervals.

10. The system according to claim 1, further comprising a plurality of photovoltaic (PV) cells connected to the plurality of inverters, respectively,
each inverter of the plurality of inverters being a solar inverter.

11. A method for monitoring inverters for faults, the method comprising:
i) receiving data from a plurality of inverters;
ii) performing preprocessing on the data received from the plurality of inverters to give preprocessed data;
iii) calculating a Z-score for each inverter of the plurality of inverters using the preprocessed data, the Z-score being a measure of how far away a value for the respective inverter of an inverter property is from an expected mean value for the inverter property;
iv) upon the Z-score for a respective inverter being at or below a predetermined threshold, determining that the respective inverter is operating normally;
v) upon the Z-score for a respective inverter exceeding the predetermined threshold, determining that a fault exists with the respective inverter;
vi) utilizing a machine learning (ML) model on the preprocessed data and the Z-scores for the plurality of inverters to determine if a fault exists in any inverter of the plurality of inverters; and
vii) generating an alert for any inverter of the plurality of inverters determined to have a fault.

12. The method according to claim 11, the ML model being a trained ML model.

13. The method according to claim 11, the ML model being random forest, decision tree, K-Nearest Neighbor (KNN), or logistic regression.

14. The method according to claim 11, the ML model being random forest.

15. The method according to claim 11, step vi) comprising using principal component analysis (PCA) on the preprocessed data before utilizing the ML model.

16. The method according to claim 11, step vi) comprising using an autoencoder (AE) on the preprocessed data before utilizing the ML model.

17. The method according to claim 11, the performing of the preprocessing comprising removing outliers in the data, removing duplicates in the data, and interpolating missing datapoints in the data.

18. The method according to claim 11, the instructions when executed further comprising:
viii) shutting down any inverter of the plurality of inverters determined to have a fault to allow for maintenance on said inverter.

19. The method according to claim 18, the instructions when executed further comprising:
ix) repeating steps i)-viii) at regular time intervals.

20. A system for monitoring inverters for faults, the system comprising:
a plurality of photovoltaic (PV) cells;
a plurality of inverters connected to the plurality of PV cells, respectively;
a processor in operable communication with the plurality of inverters; and
a machine-readable medium in operable communication with the processor and having instructions stored thereon that, when executed by the processor, perform the following steps:
i) receiving data from the plurality of inverters;
ii) performing preprocessing on the data received from the plurality of inverters to give preprocessed data;
iii) calculating a Z-score for each inverter of the plurality of inverters using the preprocessed data, the Z-score being a measure of how far away a value for the respective inverter of an inverter property is from an expected mean value for the inverter property;
iv) upon the Z-score for a respective inverter being at or below a predetermined threshold, determining that the respective inverter is operating normally;
v) upon the Z-score for a respective inverter exceeding the predetermined threshold, determining that a fault exists with the respective inverter;
vi) utilizing a machine learning (ML) model on the preprocessed data and the Z-scores for the plurality of inverters to determine if a fault exists in any inverter of the plurality of inverters;
vii) generating an alert for any inverter of the plurality of inverters determined to have a fault;
viii) shutting down any inverter of the plurality of inverters determined to have a fault to allow for maintenance on said inverter; and
ix) repeating steps i)-viii) at regular time intervals,
the ML model being a trained ML model,
the ML model being random forest, decision tree, K-Nearest Neighbor (KNN), or logistic regression,
step vi) optionally comprising using principal component analysis (PCA) or an autoencoder (AE) on the preprocessed data before utilizing the ML model, and
the performing of the preprocessing comprising removing outliers in the data, removing duplicates in the data, and interpolating missing datapoints in the data.
